(19) United States
(12) Patent Application Publication
(10) Pub. No.: US 2009/0000657 A1
(43) Pub. Date: Jan. 1, 2009

(54) Photovoltaic System And Trim Strip For Use in Roofing Applications

(76) Inventor: Gregory F. Jacobs, Oreland, PA (US)

Correspondence Address: MCDONNELL BOEHNEN HULBERT & BERGHOFF LLP, 300 S. WACKER DRIVE, 32ND FLOOR, CHICAGO, IL, 60606, US

(21) Appl. No.: 12/145,234

(22) Filed: Jun. 24, 2008

Related U.S. Application Data
(60) Provisional application No. 60/946,919, filed on Jun. 28, 2007.

(51) Int. Cl. H01L 31/042; E04D 13/15

(52) U.S. Cl. 136/251; 52/94

(57) ABSTRACT

The present invention relates generally to photovoltaic systems. The present invention relates more particularly to photovoltaic systems suitable for use in roofing applications, and to building elements useful in conjunction therewith. One aspect of the invention is a photovoltaic system for use on a building, the building having at least one edge, the building comprising a roof comprising a roof deck, the photovoltaic system comprising: a trim strip disposed along the edge of the building and having an inner surface facing toward the bulk of the building and an outer surface facing away from the bulk of the building; an electrical cable running along the inner surface of the trim strip; and at least one set of wired-together photovoltaic elements disposed on the roof deck, the set having an electrical terminus, the electrical terminus being electrically connected to the electrical cable.

### CROSS-REFERENCE TO RELATED APPLICATIONS

This application claims priority under 35 U.S.C. § 119(e) to U.S. Provisional Patent Application Ser. No. 60/946,919, filed Jun. 28, 2007, which is hereby incorporated herein by reference in its entirety.

### BACKGROUND OF THE INVENTION

1. Field of the Invention

The present invention relates generally to photovoltaic systems. The present invention relates more particularly to photovoltaic systems suitable for use in roofing applications, and to building elements useful in conjunction therewith.

2. Technical Background

The search for alternative sources of energy has been motivated by at least two factors. First, fossil fuels have become increasingly expensive due to increasing scarcity and unrest in areas rich in petroleum deposits. Second, there exists overwhelming concern about the effects of the combustion of fossil fuels on the environment due to factors such as air pollution (from NOₓ, hydrocarbons and ozone) and global warming (from CO₂). In recent years, research and development attention has focused on harvesting energy from natural environmental sources such as wind, flowing water, and the sun. Of the three, the sun appears to be the most widely useful energy source across the continental United States; most locales get enough sunshine to make solar energy feasible.

Accordingly, there are now available components that convert light energy into electrical energy. Such photovoltaic elements are often made from semiconductor-type materials such as doped silicon in either single crystalline, polycrystalline, or amorphous form. The use of photovoltaic elements on roofs is becoming increasingly common, especially as device performance has improved. They can be used to provide at least a significant fraction of the electrical energy needed for a building's overall function; or they can be used to power one or more particular devices, such as exterior lighting systems.

Often perched on an existing roof in panel form, these photovoltaic elements can often be quite visible and generally not aesthetically pleasant. Moreover, the electrical cables used to carry the photovoltaically-generated electrical power to the building's electrical system can be another source of aesthetic dissonance. Nonetheless, to date, installations have appeared to have been motivated by purely practical and functional considerations; there appears to have been no coordination between the appearance of the photovoltaic system and the roofing materials (e.g., tiles or shingles) and buildings upon which they are mounted. Lack of aesthetic appeal is especially problematic in residential buildings with non-horizontally pitched roofs; people tend to put a much higher premium on the appearance of their homes than they do on the appearance of their commercial buildings.

Accordingly, there remains a need for photovoltaic systems having more controllable and desirable aesthetics for use in roofing applications while retaining sufficient efficiency in electrical power generation, and for aesthetically appropriate building elements for use with photovoltaic systems.

### SUMMARY OF THE INVENTION

One aspect of the invention is a photovoltaic system for use on a building, the building having at least one edge, the building comprising a roof comprising a roof deck, the photovoltaic system comprising:
a trim strip disposed along the edge of the building and having an inner surface facing toward the bulk of the building and an outer surface facing away from the bulk of the building;
an electrical cable running along the inner surface of the trim strip; and
at least one set of wired-together photovoltaic elements disposed on the roof deck, the set having an electrical terminus, the electrical terminus being electrically connected to the electrical cable.

Another aspect of the invention is a photovoltaic system for use on a roof, the roof having at least one edge, the roof comprising a roof deck, the photovoltaic system comprising:
a fascia trim strip disposed along the edge of the roof and having an inner surface facing toward the bulk of the roof deck and an outer surface facing away from the bulk of the roof deck;
an electrical cable running along the inner surface of the fascia trim strip; and
at least one set of wired-together photovoltaic elements disposed on the roof deck, the set having an electrical terminus, the electrical terminus being electrically connected to the electrical cable.

Another aspect of the invention is a fascia trim strip having an inner surface having a channel formed therein, and an outer surface.

Another aspect of the invention is a method of finishing a photovoltaic system, the method comprising:
providing
   a roof having at least one edge, the roof comprising a roof deck,
   at least one set of wired-together photovoltaic elements disposed on the roof deck, the set having an electrical terminus, and
   an electrical cable;
providing a fascia trim strip having an inner surface and an outer surface and
disposing the fascia trim strip along the edge of the roof with its inner surface facing toward the bulk of the roof deck and its outer surface facing away from the bulk of the roof deck, so that the electrical cable runs along the inner surface of the fascia trim strip and is electrically connected to the terminus.

Another aspect of the invention is a building edge disposed at an edge of a building, the building edge comprising
a trim strip having an inner surface and an outer surface, the trim strip being disposed along the edge of the building with its inner surface facing toward the bulk of the building and its outer surface facing away from the bulk of the building; and
an electrical cable running along the inner surface of the trim strip.

### BRIEF DESCRIPTION OF THE DRAWINGS

FIG. 1 is a top perspective schematic view of a photovoltaic system according to one embodiment of the invention;

FIG. 2 is a cross-sectional schematic view of the photovoltaic system of FIG. 1;

FIG. 3 is a perspective schematic view of a fascia trim strip according to one embodiment of the invention;

FIG. 4 is a cross-sectional schematic view of a photovoltaic system according to another embodiment of the invention;

FIG. 5 is a cross-sectional schematic view of a photovoltaic system according to another embodiment of the invention;

FIG. 6 is a cross-sectional schematic view of a photovoltaic system having a fascia trim strip with a horizontally-projecting tab;

FIG. 7 is a top perspective schematic view of a photovoltaic system according to one embodiment of the invention;

FIG. 8 is a top perspective schematic view of a photovoltaic system according to another embodiment of the invention; and

FIG. 9 is a perspective view of a structure having a roof bearing a photovoltaic system.

### DETAILED DESCRIPTION OF THE INVENTION

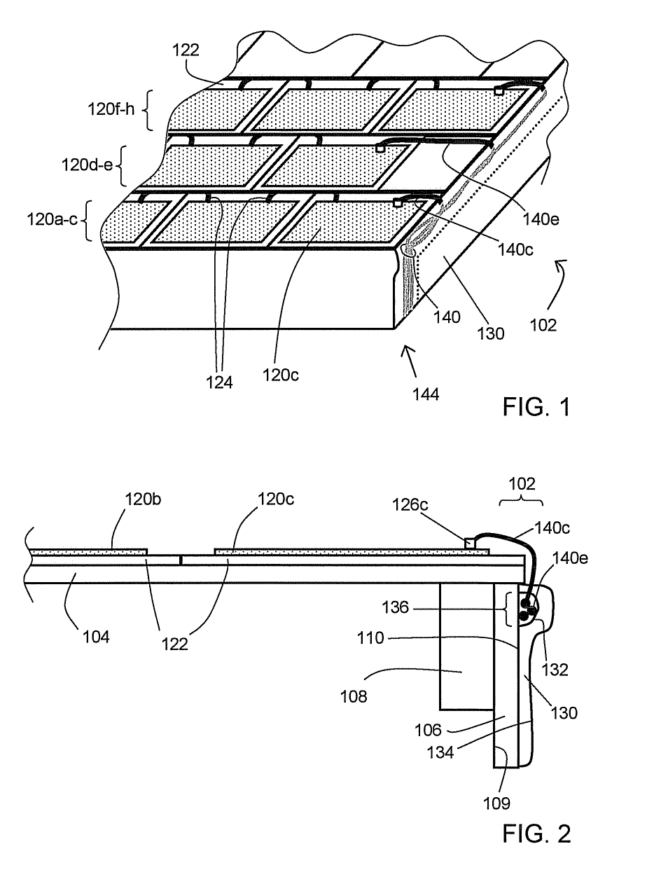

One aspect of the invention is a photovoltaic system for use on a building. The building has at least one edge, and comprises a roof comprising a roof deck. The photovoltaic system comprises a trim strip disposed along the edge of the building and having an inner surface facing toward the bulk of the building and an outer surface facing away from the bulk of the building; an electrical cable running along the inner surface of the trim strip; and at least one set of wired-together photovoltaic elements disposed on the roof deck, the set having an electrical terminus, the electrical terminus being electrically connected to the electrical cable. One embodiment of the invention is shown in FIGS. 1 and 2. While this and other embodiments of the invention are described with respect to a fascia trim strip disposed along the edge of the roof, the person of skill in the art will understand that the trim strip can be located elsewhere on the building, as described in more detail below.

One embodiment of the invention is shown in FIGS. 1 and 2. The photovoltaic system according to this embodiment of the invention is suitable for use on a roof, which has an edge 102, and which includes a roof deck 104. The edge can be, for example, a rake edge as shown in FIG. 1. In other embodiments of the invention, the edge is an eave edge. In certain embodiments of the invention, and as shown in FIG. 2, the roof also includes a fascia board 106 disposed along the edge of the roof. The fascia board 106 can be disposed, for example, along the underside of the roof deck 104 (e.g., attached to a support beam 108 as shown in FIG. 2), or alternatively can be disposed along the edge of the roof deck. The fascia board 106 has an inner surface 109 facing toward the bulk of the roof deck 104, and an outer surface 110 facing away from the bulk of the roof deck 104. In other embodiments of the invention, the roof does not include a fascia board.

The photovoltaic system includes at least one set of wired-together photovoltaic elements disposed on the roof deck. For example, in the embodiment shown in FIGS. 1 and 2, photovoltaic elements 120 are disposed on the roof deck 104, wired together in three sets, 120a-c; 120d-e, and 120f-h. In the embodiment shown in FIGS. 1 and 2, each of the photovoltaic elements 120 is integrated with a roofing element 122. In other embodiments of the invention, the photovoltaic elements can be disposed on top of an already-installed roofing material.

Photovoltaic elements 120 can be based on any photovoltaic material system, such as monocrystalline silicon; polycrystalline silicon; amorphous silicon; III-V materials such as indium gallium nitride; II-VI materials such as cadmium telluride; and more complex chalcogenides (group VI) and pnicogenides (group V) such as copper indium diselenide. For example, one type of suitable photovoltaic element includes an n-type silicon layer (doped with an electron donor such as phosphorus) oriented toward incident solar radiation on top of a p-type silicon layer (doped with an electron acceptor, such as boron), sandwiched between a pair of electrically-conductive electrode layers. Photovoltaic element 120 can also include structural elements such as a substrate such as an ETFE or polyester backing; a glass plate; or an asphalt non-woven glass reinforced laminate such as those used in the manufacture of asphalt roofing shingles; one or more protectant or encapsulant materials such as EVA and ETFE; one or more covering materials such as glass or plastic; mounting structures such as clips, holes, or tabs; and one or more optionally connectorized electrical cables. Thin film photovoltaic materials and flexible photovoltaic materials can be used in the construction of photovoltaic elements for use in the present invention. In one embodiment of the invention, the photovoltaic element is a monocrystalline silicon photovoltaic element or a polycrystalline silicon photovoltaic element.

Roofing element 122 can be based on any roofing material. Examples of roofing materials suitable for use in this aspect of the invention include shingles, tiles, panels, membranes and shakes, made from such materials as asphalt, polymeric materials, ceramic materials, stone, cementitious materials, and wood. In embodiments of the invention in which the photovoltaic element is integrated with a roofing element, the integration can be achieved in many ways, for example as described in U.S. patent application Ser. No. 11/742,909 and U.S. Provisional Patent Applications Ser. Nos. 60/946,881 and 60/946,902, each of which is hereby incorporated herein by reference.

In the embodiment described in FIGS. 1 and 2, the photovoltaic elements are shown as being individually associated (e.g., integrated) with roofing elements. The photovoltaic elements of the present invention can also be provided as a stand-alone module (e.g., a commonly-used rack-mounted array mounted on an existing roof).

In the embodiment of the invention shown in FIG. 1, the photovoltaic element within each set is shown as being wired together in series, with the connections being made by the connecting cables 124 underneath the next-higher course of roofing elements. Each set of photovoltaic elements can, however, be wired together in any fashion, such as in series, in parallel, or in series-parallel.

Each set of wired-together photovoltaic elements includes an electrical terminus. The electrical terminus can be, for example, the end of a cable that is electrically connected to a photovoltaic element of the set of wired-together photovoltaic elements. In other embodiments of the invention, the electrical terminus is an electrical terminal of a photovoltaic element of the set of wired-together photovoltaic elements. For example, as shown in FIGS. 1 and 2, photovoltaic element 120c includes terminus 126c, which is adapted to electrically connect the wired-together set of photovoltaic elements to the rest of the photovoltaic system.

The photovoltaic system also includes a trim strip disposed along the edge of the building and having an inner surface facing toward the bulk of the building and an outer surface facing away from the bulk of the building. In one embodiment of the invention, the trim strip is a fascia trim strip and is disposed along the dege of the roof with its inner surface facing toward the bulk of the roof deck and its outer surface facing away from the bulk of the roof deck. For example, in the embodiment of FIGS. 1 and 2, fascia trim strip 130 has an inner surface 132 affixed to the outer surface 110 of the fascia trim board 106, and an outer surface 134 facing away from the bulk of the rook deck 104. The trim strip can be made from any of a number of materials, including polymeric materials such as vinyl materials typically used in architectural siding and foamed polymer materials (e.g., foamed PVC), wood, and metals such as aluminum.

The outer surface of the trim strip can be configured to provide an aesthetically desirable appearance along the edge of the building. For example, the outer surface of the trim strip can have a surface relief formed thereon (e.g., as a linear feature). The outer surface of the trim strip can also have a pattern formed thereon, for example with ink or other structural features.

The photovoltaic system also includes an electrical cable running along the inner surface of the trim strip. For example, in the embodiment shown in FIGS. 1 and 2, there are three electrical cables 140 running along the inner surface 132 of the fascia trim strip 130. Electrical cable 140c, for example, is connected to the electrical terminus (i.e., electrical terminal 126) of the set of wired-together photovoltaic elements 120a-c, and runs through a hole formed in the fascia trim strip 130. It runs with electrical cable 140e along the inner surface 132 of the fascia trim strip down to the corner 144 of the roof. At the corner of the roof, electrical cable 140c leaves the inner surface of the fascia trim strip, for example to be routed along the soffit and wall and eventually to be connected to an inverter or an electrical junction (not shown). As used herein, an electrical cable can be a single cable or wire, or rather can be formed from one or more electrically connected segments.

The trim strip can have a channel formed in its inner surface, in which the electrical cable is disposed. For example, as shown in FIG. 2, fascia trim strip 130 has a channel 136 formed in its inner surface 132. Electrical cables 140 are disposed in the channel 136 as they run along the inner surface of the fascia trim strip. The channel can be open, optionally with its opening held against some part of the building (e.g., as shown in FIG. 2), or closed (e.g., in the form of a section of conduit). Another aspect of the invention is a trim strip, as described herein, having an inner surface having a channel formed therein, and an outer surface.

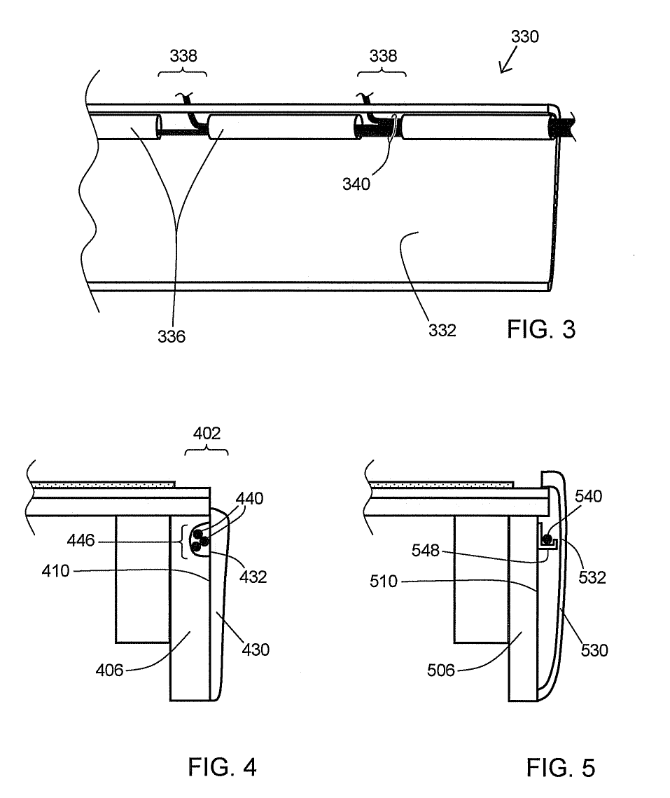

In certain embodiments of the invention, the trim strip includes one or more cable holding structures on its inner surface. The one or more cable holding structures can be, for example, one or more sections of conduit. The fascia trim strip 330 shown in FIG. 3, has conduit sections 336 on its inner surface 332. When installed, electrical cables 340 are held by the conduit sections 336. The breaks 338 between sections allow additional electrical cables to be introduced. In other embodiments of the invention, sections of conduit can have holes formed therein to allow electrical cables to be introduced. Other cable holding structures can also be used in the present invention. For example, in other embodiments of the invention the one or more cable holding structures can be one or more sections of cable holding tray, one or more clips, or one or more hooks. In other embodiments of the invention, the electrical cable is attached to the inner surface of the trim strip, for example with an adhesive, tacks, nailed-in cable holders or staples.

In another embodiment of the invention, the edge of the building has a lateral outer surface having a channel formed therein, with the electrical cable being disposed within the channel. For example, in the embodiment shown in FIG. 4, the edge 402 of the roof has a lateral outer surface (i.e., the outer surface 410 of fascia board 406). The lateral outer surface has a channel 446 formed in it, in which the electrical cables 440 are disposed. The fasica trim strip 430 closes the channel, so that the electrical cables 440 run along its inner surface 432.

In certain embodiments of the invention, the lateral outer surface of the building has one or more cable holding structures disposed thereon. The one or more cable holding structures can be, for example, one or more sections of cable holding tray. For example, in the embodiment shown in FIG. 5, the lateral outer surface of the roof (i.e., the outer surface 510 of fascia board 506) has a section of cable holding tray 548 disposed on it, by which the electrical cable 540 is held. The fascia trim strip 530 encloses the section of cable holding tray 548, so that the electrical cable 540 runs along its inner surface 532. Other cable holding structures can also be used in the present invention. For example, in other embodiments of the invention the one or more cable holding structures can be one or more sections of conduit, one or more clips, or one or more hooks. In other embodiments of the invention, the electrical cable is attached to the lateral outer surface of the building, for example with an adhesive, tacks nailed-in cable holders or staples.

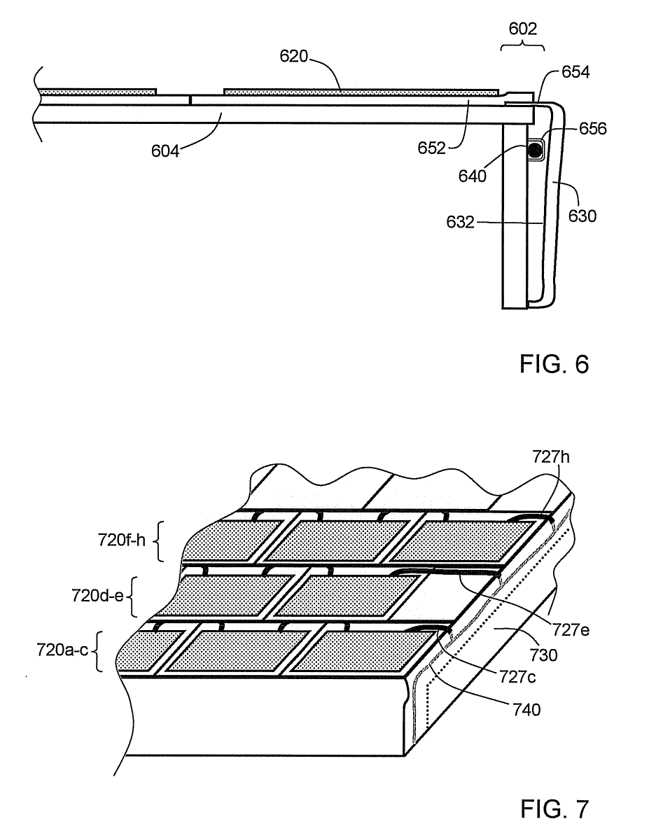

As described above, in some embodiments of the invention, the trim strip is a fascia trim strip disposed along the edge of a roof. In one such embodiment of the invention, the roof further includes one or more edge roofing elements disposed on the roof deck along the edge of the roof. The fascia trim strip has a tab projecting horizontally therefrom, which is diposed between each edge roofing element and the roof deck. The horizontally-projecting tab is at least partially disposed between each edge roofing element and the roof deck. For example, as shown in FIG. 6, the roof includes an edge roofing element 652 disposed on the roof deck 604 along the edge 602 of the roof. In the embodiment shown in FIG. 6, the edge roofing element 652 has a photovoltaic element 620 disposed thereon. However, in other embodiments of the invention, one or more of the edge roofing elements does not have a photovoltaic element disposed thereon. Fascia trim strip 630 has tab 654 projecting horizontally therefrom. The tab can, for example, run substantially the entire length of the fascia trim strip. In other embodiments of the invention, the tab can have short breaks in it to admit electrical cables to its inner surface. Tab 654 is at least partially disposed between the edge roofing element 652 and the roof deck 604. In this way, the fascia trim strip can act as a drip edge, keeping water from infiltrating to its inner surface. An electrical cable 640 is disposed along the inner surface 632 of fascia trim strip 630, and is held in place by a nailed-in fastener 656.

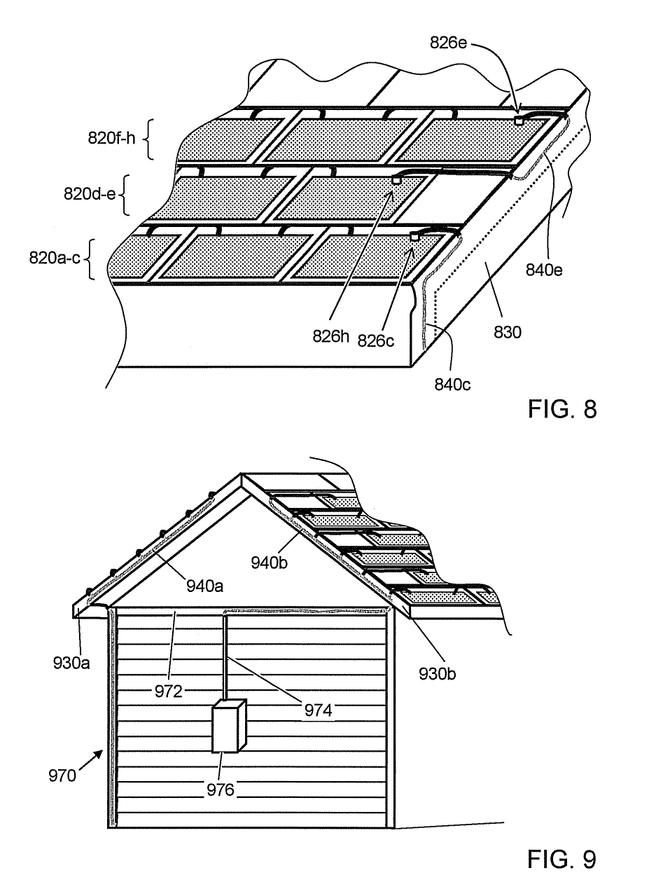

In the embodiment shown in FIGS. 1 and 2, each of the electrical cables 140 starts at a photovoltaic element 120, enters the fascia trim strip 130, and runs in along the inner surface 132 of fascia trim strip 130. Other embodiments of the invention can have different electrical connection schemes, and therefore can have different arrangements of electrical cables. For example, in the embodiment of the invention shown in FIG. 7, each set of photovoltaic elements 720a-c, 720d-e and 720f-h is connected in series, with the courses being connected to one another in parallel. Electrical cable 740 runs along the inner surface of fascia trim strip 730, and forms one of the parallel arms of the photovoltaic circuit. The electrical terminus of each set of photovoltaic elements (720a-c, 720d-e and 720f-h) is an electrical terminal cable (727c, 727e and 727h) which enters the fascia trim strip and connects to electrical cable 740. In the embodiment of FIG. 7, the electrical terminal cables 727c, 727e and 727h are shown as being exposed. In other embodiments of the invention, the electrical terminal cables can be at least partially covered by next-higher course of roofing elements. As another example, in the embodiment shown in FIG. 8, the sets of photovoltaic elements 820a-c, 820d-e and 820f-h are connected to one another in series. Electrical cable 840e connects the electrical terminal 826e of photovoltaic element 820e to the electrical terminal 826h of photovoltaic element 820h by entering the fascia trim strip 830 and running along its inner surface between the sets of photovoltaic elements. Electrical cable 840c runs from electrical terminal 826c of photovoltaic element 820c, along the inner surface of fascia trim strip 830, and down off of the roof.

In one embodiment of the invention, shown in FIG. 9, an electrical cable can emerge from the fascia trim strip and be directed to other parts of the building. For example, electrical cable 940a runs from fascia trim strip 930a, along the inner surface of corner trim strip 970, and down to the basement. An example of a suitable corner trim strip is a Super Corner, available from CertainTeed Corporation. In another example, electrical cable 940b runs from fascia trim strip 930b, along the inner surface of cornice trim strip 972, down conduit 974 and into an electrical junction box 976.

The electrical cables can enter the trim strips, for example, through holes formed therein. The holes can be sealed with a weather-resistant adhesive. The electrical cables can also enter the trim strips from the underside of an edge.

As noted above, the trim strip can be disposed along the edge of the building at locations other than along the roof edge. For example, the trim strip can be a corner trim strip disposed along a vertical-extending corner of a building. In other embodiments of the invention, the trim strip is a cornice trim strip disposed beneath a roof section. The trim strip can also be disposed along a window or a door, for example as casing trim strip. The trim strip can also be a pilaster trim strip or a moulding trim strip.

Another aspect of the invention is a method of finishing a photovoltaic system. The method comprises providing a roof having at least one edge, the roof comprising a roof deck, at least one set of wired-together photovoltaic elements disposed on the roof deck, the set of photovoltaic elements having an electrical terminus, and an electrical cable, as described above. The method also comprises providing a fascia trim strip having an inner surface and an outer surface, as described above. The method further comprises disposing the fascia trim strip along the edge of the roof, with its inner surface facing toward the bulk of the roof deck and its outer surface facing away from the bulk of the roof deck. The fascia trim strip is disposed so that the electrical cable runs along the inner surface of the fascia trim strip and is electrically connected to the electrical terminus. For example, in embodiments where the electrical cable is held by a cable holding structure or in a channel on the inner surface of the fascia trim strip, or is attached to the inner surface of the fascia trim strip, the electrical cable can be assembled with the fascia trim strip, then the entire assembly can be disposed along the roof edge. In embodiments where the electrical cable is held by a cable holding structure or a channel on the lateral outer surface of the edge of the roof, or is attached to the lateral outer surface of the edge of the roof, the electrical cable can be assembled with the lateral outer surface of the edge of the roof before the fascia trim strip is disposed along it. In embodiments where the electrical cable enters the trim strip through a hole formed therein, the electrical cable can be fed through the hole before the fascia trim strip is disposed along the roof edge.

In certain embodiments according to this aspect of the invention, the fascia trim strip has a tab projecting horizontally therefrom, and the method further includes the step of at least partially disposing the tab between the roof deck and one or more edge roofing elements disposed on the roof deck. For example, if the photovoltaic system is being installed on a new roof, the fascia trim strip can be disposed along the edge with its tab on the roof deck, then the one or more edge roof elements can be disposed on top of the tab. If the photovoltaic system is installed on an existing roof bearing existing edge roofing elements, the tab can be inserted between the edge roofing elements and the roof deck as the fascia trim strip is being disposed along the edge of the roof deck.

Another aspect of the invention is a building edge disposed at an edge of a building. The building edge comprises a trim strip having an inner surface and an outer surface, as described above. The inner surface faces toward the bulk of the building and the outer surface faces away from the bulk of the building, as described above. The building edge also comprises a cable running along the inner surface of the trim strip, as described above. The cable can be, for example, an electrical cable. The electrical cable can, for example, be electrically connected to the electrical terminus of a wired-together set of photovoltaic elements. In other embodiments of the invention, the electrical cable is electrically connected to some other electrical or electronic device disposed on the building, for example, an antenna, a satellite dish, a light, a sensor, a display, or a speaker. In some embodiments of the invention, the electrical cable is capable of transmitting electrical power. However, in other embodiments of the invention, the electrical cable is capable of transmitting an electric signal. In still other embodiments of the invention, the cable is an optical fiber cable. The optical fiber cable can, for example, connect an optical signal transceiver in the building to an optical transmission system.

In certain embodiments according to this aspect of the invention, as described above, the building edge is a roof edge, the trim strip is a fascia trim strip, and the edge of the building is an edge of the roof.

In certain embodiments of the invention, the outer surface of the trim strip has a surface relief or pattern formed thereon.

It will be apparent to those skilled in the art that various modifications and variations can be made to the present invention without departing from the scope of the invention. Thus, it is intended that the present invention cover the modifications and variations of this invention provided they come within the scope of the appended claims and their equivalents.

What is claimed is:

1. A photovoltaic system for use on a building, the building having at least one edge, the building comprising a roof comprising a roof deck, the photovoltaic system comprising:
a trim strip disposed along the edge of the building and having an inner surface facing toward the bulk of the building and an outer surface facing away from the bulk of the building;
an electrical cable running along the inner surface of the trim strip; and
at least one set of wired-together photovoltaic elements disposed on the roof deck, the set having an electrical terminus, the electrical terminus being electrically connected to the electrical cable.

2. The photovoltaic system of claim 1, wherein the trim strip has a channel formed in its inner surface, and wherein the electrical cable is disposed within the channel.

3. The photovoltaic system of claim 1, wherein trim strip includes one or more cable holding structures on its inner surface, and wherein the electrical cable is held by the one or more cable holding structures.

4. The photovoltaic system of claim 1, wherein the electrical cable is attached to the inner surface of the trim strip.

5. The photovoltaic system of claim 1, wherein the edge of the building has a lateral outer surface having a channel formed therein, and wherein the electrical cable is disposed within the channel.

6. The photovoltaic system of claim 1, wherein the edge of the building has a lateral outer surface having one or more cable holding structures disposed thereon, and wherein the electrical cable is held by the one or more cable holding structures.

7. The photovoltaic system of claim 1, wherein the edge of the building has a lateral outer surface, and wherein the electrical cable is attached to the lateral outer surface.

8. The photovoltaic system of claim 1, wherein the edge of the building is the edge of the roof, wherein the trim strip is a fascia trim strip, and wherein the inner surface of the fascia trim strip faces toward the bulk of the roof deck and the outer surface of the fascia trim strip faces away from the bulk of the roof deck.

9. The photovoltaic system of claim 8, wherein the roof further includes one or more edge roofing elements disposed on the roof deck along the edge of the roof, wherein the fascia trim strip has a tab projecting horizontally therefrom, which is at least partially disposed between each edge roofing element and the roof deck.

10. The photovoltaic system of claim 1, wherein the outer surface of the trim strip has a surface relief or a pattern formed thereon.

11. The photovoltaic system of claim 1, wherein the trim strip is a fascia trim strip, a corner trim strip, a cornice trim strip, a casing trim strip, a pilaster trim strip or a moulding trim strip.

12. A method of finishing a photovoltaic system, the method comprising:
providing
a roof having at least one edge, the roof comprising a roof deck,
at least one set of wired-together photovoltaic elements disposed on the roof deck, the set having an electrical terminus, and
an electrical cable;
providing a fascia trim strip having an inner surface and an outer surface and
disposing the fascia trim strip along the edge of the roof with its inner surface facing toward the bulk of the roof deck and its outer surface facing away from the bulk of the roof deck, so that the electrical cable runs along the inner surface of the fascia trim strip and is electrically connected to the electrical terminus.

13. The method of claim 12, wherein the outer surface of the fascia trim strip has a surface relief or a pattern formed thereon.

14. The method of claim 12, wherein the electrical cable is held by a cable holding structure or in a channel on the inner surface of the fascia trim strip, or is attached to the inner surface of the fascia trim strip; and wherein disposing the fascia trim strip comprises assembling the electrical cable with the fascia trim strip, then disposing the assembly so formed along the roof edge.

15. The method of claim 12, the electrical cable is held by a cable holding structure or a channel on the lateral outer surface of the edge of the roof, or is attached to the lateral outer surface of the edge of the roof, and wherein the disposing the fascia trim strip comprises assembling the electrical cable with the lateral outer surface of the edge of the roof; then disposing the fascia trim strip along the edge of the roof.

16. A building edge disposed at an edge of a building, the building edge comprising
a trim strip having an inner surface and an outer surface, the trim strip being disposed along the edge of the building with its inner surface facing toward the bulk of the building and its outer surface facing away from the bulk of the building; and
a cable running along the inner surface of the trim strip.

17. The building edge of claim 16, wherein the building edge is a roof edge, the trim strip is a fascia trim strip, and the edge of the building is an edge of the roof.

18. The building edge of claim 16, wherein the outer surface of the trim strip has a surface relief or pattern formed thereon.
